(19) United States
(12) Patent Application Publication
(10) Pub. No.: US 2008/0102380 A1
(43) Pub. Date: May 1, 2008

(54) High density lithographic process

(76) Inventor: Pawitter S. Mangat, Gilbert, AZ (US)

Correspondence Address: INGRASSIA FISHER & LORENZ, P.C., 7150 E. CAMELBACK, STE. 325, SCOTTSDALE, AZ, 85251, US

(21) Appl. No.: 11/590,495

(22) Filed: Oct. 30, 2006

(51) Int. Cl. G03F 1/00; C23F 1/00; B44C 1/22; C03C 15/00; C03C 25/68

(52) U.S. Cl. 430/5; 216/2; 216/41

(57) ABSTRACT

A method is provided for patterning monolithically integrated features having a 1:1 ratio. The method comprises forming a first etch barrier layer (18) over a base layer (14) and applying (52) a template (20) to pattern (52) first printed features (26) in the first etch barrier layer (18). The first etch barrier layer (18) is etched (54) to form second printed features (32) in the base layer (14). A second etch barrier layer (34) is formed over the base layer (14) and the template (20) is applied to pattern (58) third printed features (38) in the second etch barrier layer (34). The second etch barrier layer (34) is etched (60) to form fourth printed features (42) in the base layer (14).

### FIELD OF THE INVENTION

The present invention generally relates to semiconductor devices, microelectronic devices, micro electro mechanical devices, microfluidic devices, photonic devices, and more particularly to a method for making these devices using a lithographic imprinting process.

### BACKGROUND OF THE INVENTION

The fabrication of integrated circuits, microelectronic devices, micro electro mechanical devices, microfluidic devices, and photonic devices, involves the creation of several layers of materials that interact in some fashion. One or more of these layers may be patterned so various regions of the layer have different electrical characteristics, which may be interconnected within the layer or to other layers to create electrical components and circuits. These regions may be created by selectively introducing or removing various materials. The patterns that define such regions are often created by lithographic processes. Conventional lithographic processes include optical or contact printing. More recently, nano-imprint lithography is being explored for printing high resolution features. In case of imprint or contact printing, a template may be applied under pressure to form features in a layer. Optionally, heat may be applied to the layer, or radiation may be applied through the template (mask), to harden the features. In another example, a layer of photoresist material is applied onto a layer overlying a wafer substrate. A photomask (containing clear and opaque areas) is used to selectively expose this photoresist material by a form of radiation, such as ultraviolet light, electrons, or x-rays. Either the photoresist material exposed to the radiation, or that not exposed to the radiation, is removed by the application of a developer. An etch may then be applied to the layer not protected by the remaining resist, and when the resist is removed, the layer overlying the substrate is patterned.

Lithographic processes such as that described above are typically used to transfer patterns from a photomask to a device. As feature sizes on devices, for example, semiconductors, decrease into the submicron range, there is a need for new lithographic processes, or techniques, to create patterns that are small and highly-dense, such as sub 50 nanometers features. For example, there is a need to fabricate ultra high capacity memory or storage devices, optoelectronic or photonic devices, or grating or optical filters for a variety of consumer applications. Many of these technologies require nanometer dimensional periodic array cells that go gar beyond the expected limits of conventional lithography used in today's memory chips. The next generation memory and storage products for use in a wide range of future consumer electronics/mobile products will require data storage capacities that exceed the physical limitations of today's semiconductor memory technology. Several new lithographic techniques which accomplish this need and have a basis in imprinting and stamping have been proposed. One in particular, nano-imprint lithography, has been shown to be capable of patterning structures as small as 10 to 20 nm. As such, a wide variety of feature sizes may be drawn on a single wafer. Certain problems exist though with the nano-imprint template fabrication methodology as described above.

Furthermore, as the features are reduced to below 50 nm, it becomes difficult to fabricate a template having uniform features which can be transferred to the receiving material. The challenges of fabricating a template or photomask with sub 50 nm features for contact printing far exceed the technologies that are currently available for a high throughput manufacturing process. In particular, problems exist with respect to: (i) uniform writing of dense (1:1) sub 50 nanometer features due to image distorting charging effects during electron beam patterning of the template; and (ii) uniform etching of the quartz template with dense sub 50 nanometer features. The conventional optical lithography uses a 4× or 5× reduction process where the constraints on the template or photomask are reduced but the complexity in the reduction optics is greatly increased resulting in high cost of the manufacturing process. Hence, a solution is needed to address the printing of sub 50 nm features for next generation of application devices discussed above.

Accordingly, it is desirable to provide an improved method for patterning monolithically integrated features having a 1:1 or 1:0.5 ratio. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method is provided for contact printing on a device using a template. The method comprises applying the template a first time to form a first plurality of printed features in a surface of the device and applying the template a second time to form a complementary second plurality of printed features in the surface of the device.

### BRIEF DESCRIPTION OF THE DRAWINGS

The present invention will hereinafter be described in conjunction with the following drawing figures, wherein like numerals denote like elements, and

FIG. 1 is a partial cross sectional view of layers of a monolithically integrated structure prior to processing with a template;

FIG. 2 is a partial cross sectional view of a template;

FIGS. 3-15 are partial cross sectional views and top views of the application of the template of FIG. 2 to the structure of FIG. 1;

FIG. 16 is a flow chart of the steps in accordance with the exemplary embodiment of FIGS. 3-15; and

FIGS. 17-18 are partial cross sectional views of another application of the template of FIG. 2 to the structure of FIG. 1.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The distinction between a lithographic mask and a lithographic template should be noted. A lithographic mask is used as a stencil to impart an aerial image of light into a photoresist material. A lithographic template has a relief image etched into its surface, creating a form or mold. A pattern is defined when a photocurable liquid flows into the relief image and is subsequently cured. The attributes necessary for masks and templates, therefore, are quite different. However, as used herein, the word “template” shall refer to attributes and functions associated with both a template and a mask.

In order to lithographically pattern a high density integrated circuit, e.g., memory or storage media, using a template, it is desirable to have 1:1 features in the range of 5.0 to 25 nm in size equally spaced imprinted on a target substrate. Template fabrication at these dimensions pose a problem due to the 1× replication. In other words, the template must be fabricated at the same small dimensions, with uniform spacing and well defined features. As described in more detail below, performing multiple imprints using a template having, e.g., 1:2 or 1:3 features, reduces the complexity and increases the yield. The template having larger than 1:1 features is imprinted on a target wafer, which is then transferred into an underlying oxide layer. The wafer is coated again for imprinting, realigned, imprinted again with the same template but with a pattern offset, and then transferred into the underlying oxide layer. This process allows for fabricating a wafer having 1:1 features using template having greater than 1:1 features. Multiple exposures with the template may be accomplished. The method (and the type of template) used to imprint the features may employ a direct imprinting wherein features (physical shapes) in the template are transferred to the wafer. Optionally, heat may be applied to, or radiation may be directed through, the template to harden the features in the wafer. An alternative template comprises transparent regions within the template, wherein radiation transmitted therethrough define the features in the wafer following an etching process.

Pattern transfer on a wafer begins with an imprinted feature, such as lines or vias in the monomer layer. The monomer material is a silicon containing or non-silicon containing organic material that conforms to the shape of the template. After being exposed by a broadband light source, the monomer cross-links forming a rigid, patterned layer. A thin residual layer does exist at the base of all of the imprinted features. The residual layer is consumed during the pattern transfer of imprinted features to the underlying anti-reflective coating. The underlying anti-reflective coating is then etched, followed by an oxide etch.

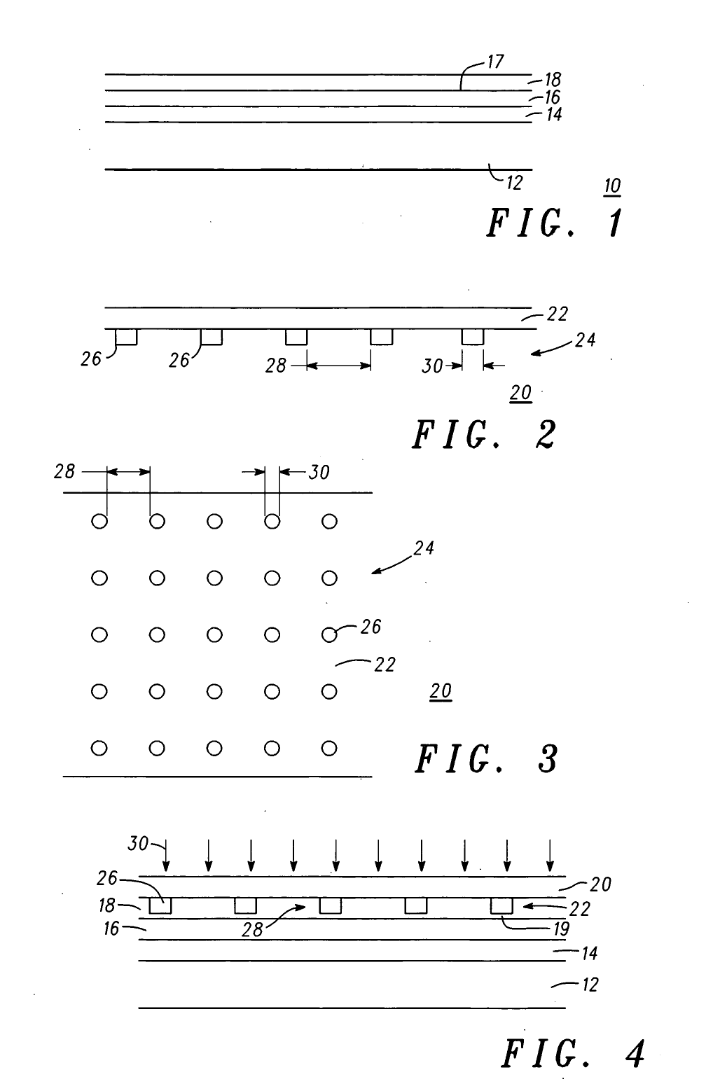

FIGS. 1-15 illustrate a plurality of process steps for fabricating an integrated circuit using multiple applications of a template in accordance with an exemplary embodiment. More specifically, FIG. 1 is a monolithically integrated structure 10 under manufacture including a substrate 12 underneath a layer 14. The substrate 12 may comprise, for example, one of silicon, silicon carbide, gallium nitride, gallium arsenide, plastic, lithium niobate, glass. Some of these materials may be subsequently etched for processing steps in fabricating certain devices, for example, MEMS (micro electro mechanical devices). The layer 14 is preferably a silicon oxide when deposited on a silicon substrate 12. By conventional methods, a transfer layer 16 is applied to layer 14. The transfer layer 16 may comprise anti-reflective coating (ARC) materials commercially available. The purpose of the ARC is two-fold: it acts as an adhesion layer for the etch barrier layer 18, and it also serves as a masking layer for final pattern transfer into the oxide layer 14. The etch barrier layer 18 is formed, typically by deposition, on the transfer layer 16. The etch barrier layer 18 may comprise any number of organic monomer, or mixture of monomers, such as acrylics, ethers, esters, epoxies, or the like for greater etch resistance, but preferably comprises a silicon containing monomer and may have a thickness in the range of 10-50 nm, but preferably in the range of 20-30 nm. Etch barrier layer 18 is preferably formed as smooth as the surface 17 of the transfer layer 16 on which it is formed. More specifically, etch barrier layer 18 is described as being formed: (i) extremely smooth (<1 nm rms, and preferably <0.3 nm rms); (ii) upon conversion to SiO₂, transmit therethrough approximately 90% or greater ultraviolet light used during subsequent processing steps; (iii) having a sufficiently low etch rate relative to the patterning layer in order to overcome any microloading effects; and (iv) having a film comprising 60-65% carbon, 30-35% Si, and N enabling the ability to be converted into SiO₂ through exposure to an oxygen reactive ion plasma. In addition, etch barrier layer 18 must have sufficient strength to survive the stresses associated with template manufacturing and subsequent handling during the fabrication of the semiconductor devices with the completed lithographic template. An optional adhesive layer (not shown) may be deposited on the substrate 12 prior to depositing the etch barrier layer 18 for improving the adhesion between the etch barrier layer 18 and the transfer layer 16. The adhesive layer 13 is between 0.5 to 50 nanometers thick and may comprise, for example, diamond like carbon, polymer like carbon, or a self assembled monolayer as the adhesive, which may be applied by plasma enhanced CVD, spun on, or vapor deposited, for example. The nano-imprint lithography process relies on photopolymerization of a low viscosity, acrylate-based solution. A silylated or silicon containing monomer provides etch resistance in the oxygen transfer etch. Crosslinker monomers provide thermal stability in the cured etch barrier and also improve its cohesive strength. Organic monomers serve as mass-persistent components and lower the viscosity of the etch barrier formulation. Photoinitiators dissociate to form radicals upon UV irradiation, and these radicals initiate polymerization.

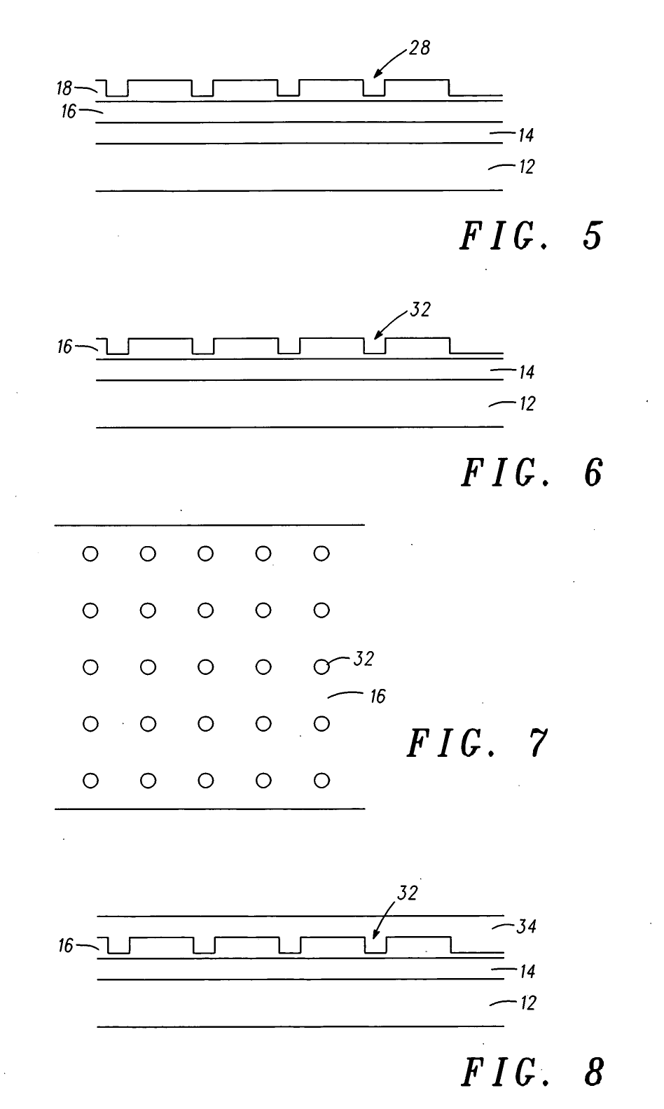

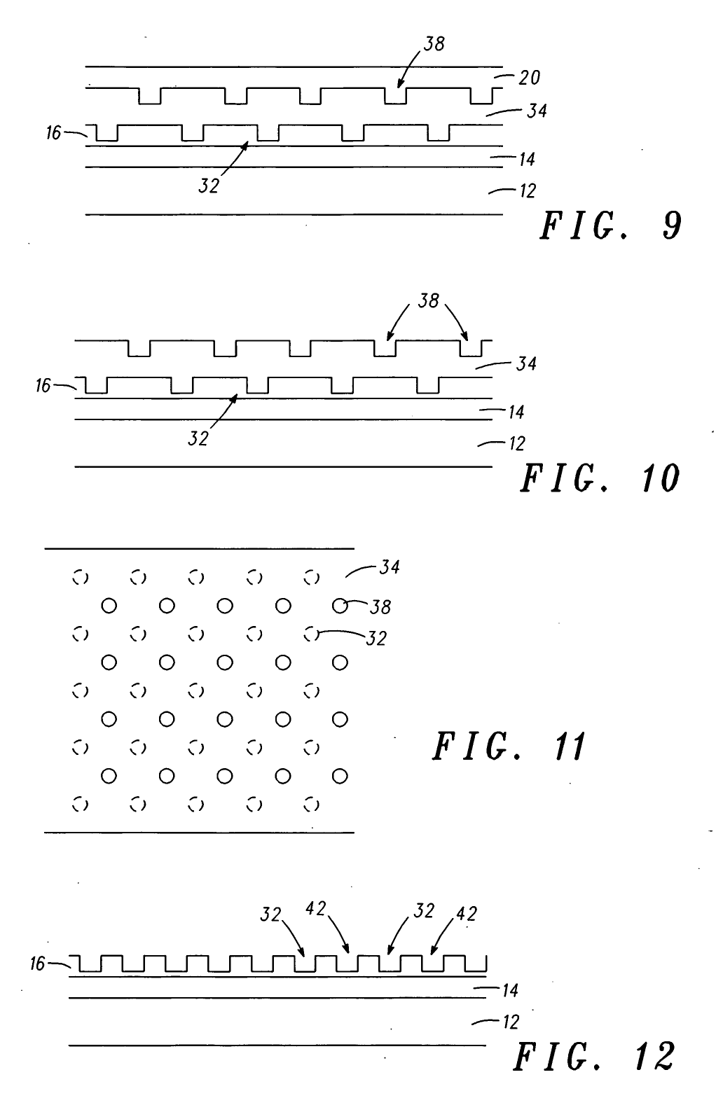

Referring to the partial cross sectional view of FIG. 2 and the bottom view of FIG. 3, a simple figure of a template 20 is shown comprising a base 22 typically manufactured of a transparent material, such as a quartz material, a polycarbonate material, a Pyrex® material, a calcium fluoride (CaF₂) material, a magnesium fluoride material (MgF₂), or any other similar type of material, that is transparent to light. Base 22 is formed of a transparent material to allow for the passage therethrough of light. A transparent patterning layer 24 may be formed in any known manner and typically include one of silicon dioxide (SiO₂), silicon nitride (SiN), silicon oxy-nitride (SiON), indium-tin-oxide (ITO), or the like. Patterning layer 24 is disclosed as generally having a thickness dependent upon the desired aspect ratio of the features for the structure 10. Specifically, patterning layer 24 will need to have sufficient mechanical strength and durability to survive the stresses associated with template manufacturing and subsequent handling during the fabrication of the semiconductor devices with the completed lithographic template. Patterning layer 24 is therefore generally disclosed as having a thickness of between 10 and 5000 nm, and a preferred thickness of at least 50 nm. Patterning layer 24 may be formed by spin coating, sputtering, vapor deposition, or the like. The patterning layer 24 comprises a plurality of pedestals 26 spaced in a 1:2 feature size. The distance 28 between each adjacent pedestal 26 is twice the distance 30 across each pedestal. Though only a small number of pedestals 26 are shown, it should be understood there typically may be many thousands or millions of pedestals 26. And though the pedestals 26 are round, it should be understood that any shape may be provided, e.g., square or rectangular. The above description of the template 20 is only one exemplary embodiment. The template 20 may be fabricated using any one of many known methods, and may, for example, comprise the template as disclosed in U.S. Pat. No. 6,580,172, or a non-transparent template used for direct imprinting.

Referring to FIG. 4, the template 20 is applied with slight pressure to the etch barrier layer 18 of the structure 10 to create the pattern comprising printed features 28 in the etch barrier layer 18 with a residual material 19 of about 2-10 nanometers remaining between the printed features and the transfer layer 16. Radiation (represented by the arrows 30) is applied through the template to harden the printed features 28. The template 20 is removed (FIG. 5) leaving the printed features 28 in the etch barrier layer 18. It is reiterated that the printed features 28 may be created by other types of templates, such as by partially transparent masks or by direct imprinting with non-transparent templates with heat optionally applied to harden the printed features 28.

The etch barrier layer 18 is then etched using an inductively coupled plasma (ICP) with fluorine-based chemistry for example in Silicon containing monomer, or any other chemistry that results in selectively transferring the pattern into the transfer layer 16, resulting in the pattern comprising printed features 32 being formed in the transfer layer 16 (FIGS. 6 and 7). Another etch barrier layer 34 is formed on the surface 36 of the transfer layer 16, including within the printed features 32 (FIG. 8).

In accordance with the exemplary embodiment, the template 20 is again applied (FIG. 9), with slight pressure to etch the barrier layer 34 to create the pattern comprising printed features 38 in the etch barrier layer 34. In this exemplary embodiment, the template 20 is offset in a lateral direction 35 (FIG. 11) at 45 degrees to the rows and columns of the printed features 32 wherein each printed feature 38 is equal distance between each of the printed features 32. Note however, in other embodiments using multiple template applications, the distance between printed features for each application of the template 20 may not be equal until all of the multiple template applications have occurred. The template 20 is then removed (FIG. 10) leaving the printed features 38 in the etch barrier layer 34. FIG. 11 illustrates the spacing of the printed features 38 in the etch barrier layer 34 and the printed features 32 (dotted lines) underlying the etch barrier layer and in the transfer layer 16.

The etch barrier layer 34 is then etched using a conventional pattern transfer process, resulting in the pattern comprising printed features 42 being formed in the transfer layer 16 (FIGS. 6 and 7) and spaced from the printed features 32. The transfer layer 16 is then etched to remove the transfer layer 16 and form printed features 44 within the layer 14 (FIGS. 13 and 14). Etching of the transfer layer to create a masking layer is done in a high temperature using a gaseous enchant. A sufficient selectivity of about 5.5:1 (ARC:EB) may be obtained using an ammonia etch process at low bias and low pressure. The printed features 28, 32, 38, and 42 all comprise the same pattern; however, each are offset from one another. The printed features 44 is that same pattern, repeated twice (in this exemplary embodiment). The pattern may be repeated more often with repeated offset applications of the template 20.

It is easily seen that using multiple applications of the template 20, many printed features may be formed in the same area. For example, FIG. 15 illustrates printed features 46 formed in the layer 14 using four applications of the template 20.

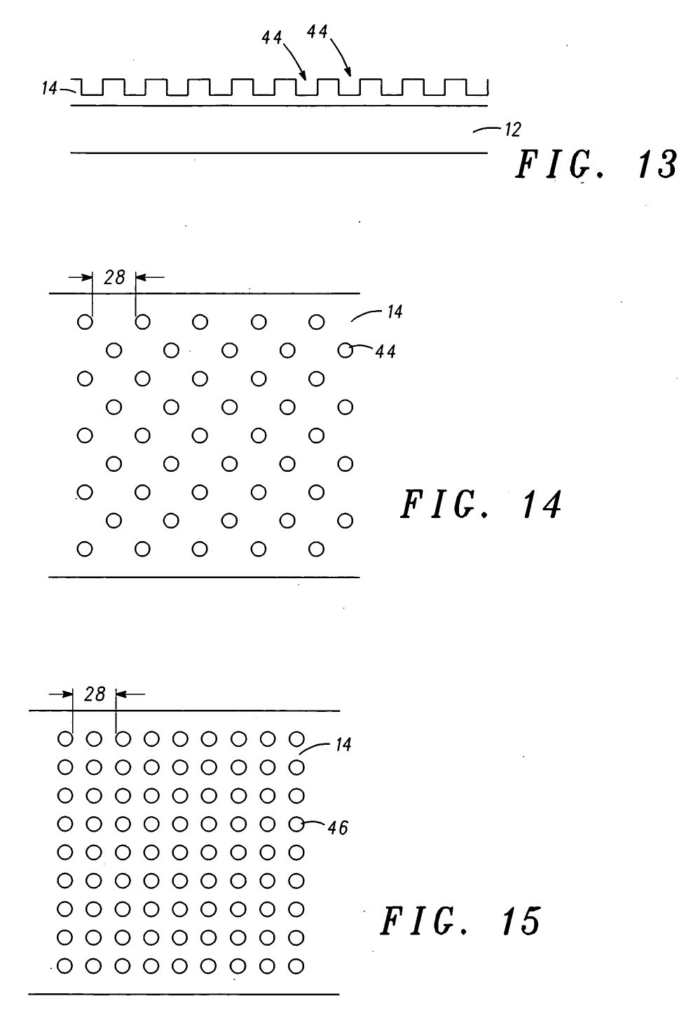

FIG. 16 is a flow chart illustrating the process of the exemplary embodiment. Printed features 26 are imprinted 52 within the etch barrier layer 18. The etch barrier layer 18 is then removed by etching 54 to form printed features 32 in the transfer layer 16. Another etch barrier layer 34 is applied 56 and imprinted 58 with printed features 38. The etch barrier layer 34 is removed by etching 60 to form printed features 42 in the transfer layer 16. Steps 56, 58, and 60 may be repeated to form additional printed features in the transfer layer 16. The transfer layer 16 is then etched, thereby forming printed features 46 in a base layer 14.

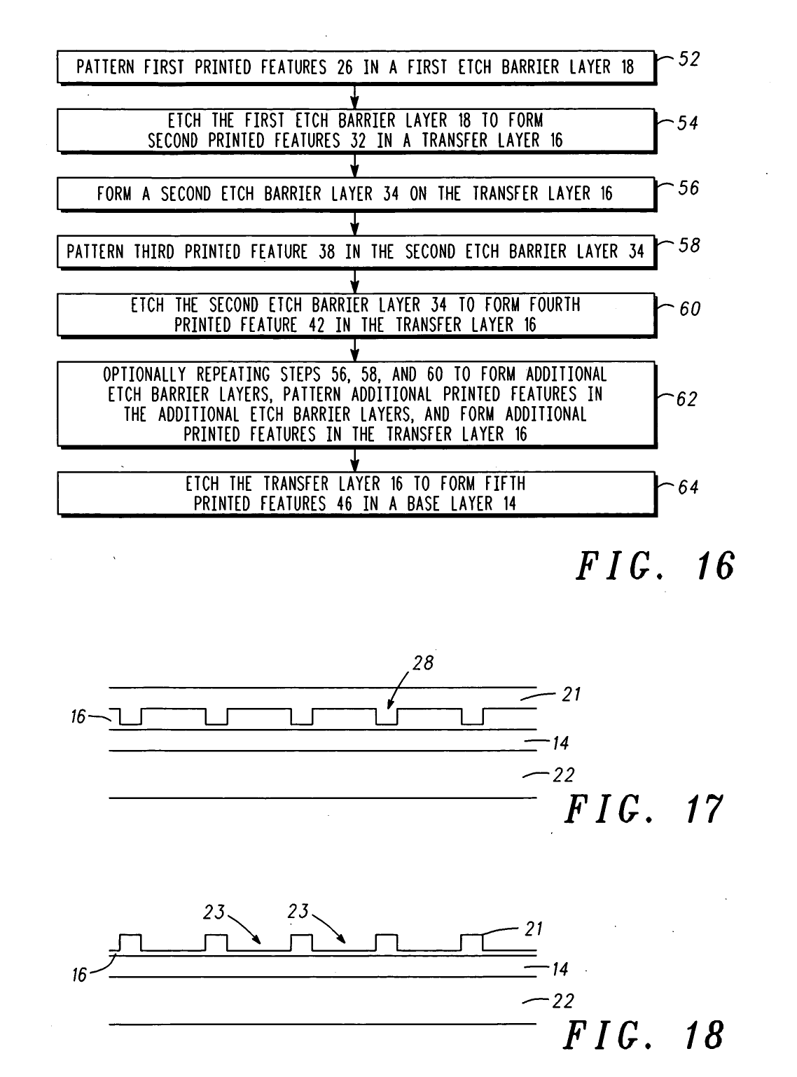

Referring to FIG. 17, another exemplary embodiment comprises applying a high silicon containing resist planarizing layer 21 on the transfer layer 16 and within the features 28 of FIG. 6. A first etch is then preformed to remove the material 21 down to the transfer layer 16 using a halogen oxygen etch under anisotropic conditions and a second etch is performed using oxygen etch under anisotropic conditions to remove at least a portion of the transfer layer 16 not underlying the material 21 to create the features 23. The second application of the template 20 is made as previously discussed.

This invention may be applied to contact printing or stamping lithography in many other technologies besides the semiconductor industry, e.g., the making of compact discs (CDs) or other such device. CDs are manufactured with a lithographic process by replicating data as a series of bumps on a plastic disc that can be read with the use of a laser beam. In a manner well known to those in the CD industry, a nickel pattern is formed by electroplating nickel onto a photoresist patterned glass master. A stamper is then formed by separating the nickel from the glass and removing the photoresist. The pattern information on the stamp is transferred into a soft and malleable injection molded polycarbonate via a stamping process. This process typically contaminates the stamp when excess polycarbonates and light dirt or soil adhere to the nickel master, causing similar problems as discussed above for the semiconductor example. A low surface energy release agent coating can be applied to the nickel master to prevent contamination.

In summary, a template having larger than 1:1 features is imprinted on a target wafer, which is then transferred into an underlying oxide layer. The wafer is coated again for imprinting, realigned, and imprinted again with the same template but with a pattern offset, and then transferred into the underlying oxide layer. This process allows for fabricating a wafer having 1:1 features using template having greater than 1:1 features. Multiple exposures with the template may be accomplished for creating even smaller ratios, e.g., 1:0.5.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method of contact printing on a device using a template, comprising:
(a) applying the template a first time to form a template pattern in a surface of the device; and
(b) offsetting and applying the template a second time to form the template pattern in the surface of the device, resulting in a device pattern on the device comprising a combination of the application of the template the first and second times.

2. The method of claim 1 wherein the device is a monolithically integrated structure.

3. The method of claim 2 wherein steps (a) and (b) comprise direct imprinting of a layer.

4. The method of claim 2 wherein the template pattern comprises features having a ratio larger than 1:1 and the device pattern comprise features having a 1:1 ratio.

5. The method of claim 2 wherein step (a) comprises forming the template pattern in a first etch barrier layer and step (b) comprises forming the second template pattern in a second etch barrier layer, and further comprising, after step (a), etching a first etch barrier layer, and after step (b), etching a second etch barrier layer, to form the device pattern in a base layer.

6. The method of claim 1 further wherein step (a) comprises forming printed features and further comprising
forming a material within the printed features; and
removing a portion of the surface other than where the filled printed features are formed.

7. A method of contact printing on a device, comprising:
forming a first etch barrier layer on a base layer;
patterning a first plurality of printed features in the first etch barrier layer;
etching the first etch barrier layer to form a second plurality of printed features in the base layer;
forming a second etch barrier layer on the base layer;
patterning a third plurality of printed features in the second etch barrier layer; and
etching the second barrier layer to form a fourth plurality of printed features in the base layer.

8. The method of claim 7 wherein the device is a monolithically integrated structure.

9. The method of claim 7 wherein the patterning a third plurality of printed features comprises offsetting the third plurality of printed features from the first plurality of printed features.

10. The method of claim 7 wherein the patterning steps comprise direct imprinting of a layer.

11. The method of claim 7 wherein the patterning steps comprise applying a template with printing features having a ratio larger than 1:1 and the first and second plurality of printed features comprise an array of features having a 1:1 ratio.

12. The method of claim 7, after patterning a first plurality of printed features, further comprising:
filling the printed features; and
etching a portion of the etch barrier layer other than the filled printed features.

13. A method of manufacturing a monolithically integrated structure, comprising:
(a) forming a base layer;
(b) forming a transfer layer on the base layer;
(c) forming a first etch barrier layer on the transfer layer;
(d) applying a template to pattern printed features in the first etch barrier layer;
(e) etching the first etch barrier layer to form the printed features in the transfer layer;
(f) forming a second etch barrier layer on the transfer layer;
(g) offsetting and applying the template to pattern the printed features in the second etch barrier layer;
(h) etching the second etch barrier layer to form the printed features in the transfer layer, resulting in the transfer layer having a combination pattern of printed features from step (e) and (h);
(i) etching the transfer layer to form the combination pattern in the base layer.

14. The method of claim 13 wherein step (g) comprises (j) offsetting the template from the application of the template in step (d) wherein each of the printed features of step (g) are equal distant from each of the printed features of step (d).

15. The method of claim 13 further comprising:
(k) after step (h) and before step (i), forming an additional etch barrier layer on the transfer layer;
(l) offsetting and applying the template to pattern the printed features in the additional etch barrier layer;
(m) etching the additional etch barrier layer to form the printed features in the transfer layer; and
(n) repeating steps (k), (l), and (m).

16. The method of claim 14 wherein steps (d) and (g) comprise applying the template having features with a ratio larger than 1:1, wherein the combination pattern comprises features having a 1:1 ratio.

17. The method of claim 13, after the applying a template step, further comprising:
filling the printed features; and
etching a portion of the etch barrier layer other than the filled printed features.
